(19) United States
(12) Patent Application Publication
(10) Pub. No.: US 2026/0050209 A1
(43) Pub. Date: Feb. 19, 2026

(54) METHODS OF FORMING PATTERNS FOR SEMICONDUCTOR DEVICEs

(71) Applicant: Samsung Electronics Co., Ltd., Suwon-si (KR)

(72) Inventors: SOYOUNG NOH, Suwon-si (KR); SEONGBO SHIM, Suwon-si (KR); MOOSONG LEE, Suwon-si (KR); CHAN HWANG, Suwon-si (KR)

(21) Appl. No.: 19/073,944

(22) Filed: Mar. 7, 2025

(30) Foreign Application Priority Data
Aug. 13, 2024 (KR) 10-2024-0108495

(51) Int. Cl. G03F 7/00; G03F 1/38; H01L 21/027

(52) U.S. Cl. CPC G03F 7/0035; G03F 1/38; H01L 21/027

(57) ABSTRACT

Provided is a method of forming patterns for a semiconductor device, the method comprising: forming an etching target film on a substrate; and forming a photoresist pattern on the etching target film, wherein the photoresist pattern includes a first exposure pattern on the etching target film and a second exposure pattern on the first exposure pattern, wherein forming the photoresist pattern comprises: forming a first photoresist film on the etching target film; forming the first exposure pattern by removing at least a portion of the first photoresist film through a first exposure process; forming a second photoresist film on the first exposure pattern; and forming the second exposure pattern by removing at least a portion of the second photoresist film through a second exposure process, wherein the photoresist pattern has a thickness that decreases from a central portion to an edge portion thereof.

### CROSS-REFERENCE TO RELATED APPLICATIONS

This application is based on and claims priority under 35 U.S.C. § 119 to Korean Patent Application No. 10-2024-0108495, filed on Aug. 13, 2024, in the Korean Intellectual Property Office, the disclosure of which is incorporated by reference herein in its entirety.

### BACKGROUND OF THE INVENTION

The inventive concept relates to methods of forming patterns for semiconductor devices, and more particularly, to methods of forming patterns for semiconductor devices including patterns with height differences.

In manufacturing highly scaled, highly integrated semiconductor devices, implementing fine patterns with fine dimensions that exceed (e.g., less or smaller than) the resolution limit of the photolithography process may be needed. Accordingly, there may be a demand for technology that can form fine (e.g., less or smaller) patterns within the resolution limit of existing photolithography processes.

Additionally, as semiconductor devices become more diverse, research is being conducted to form various patterns using semiconductor manufacturing process technology.

### SUMMARY OF THE INVENTION

The inventive concept may provide methods of forming patterns for semiconductor devices with improved reliability.

The inventive concepts are not limited to the mentioned above, and other inventive concepts not mentioned are clearly understood by those skilled in the art from the description below.

According to an aspect of the inventive concept, there is provided a method of forming patterns for a semiconductor device.

The method includes forming an etching target film on a substrate; and forming a photoresist pattern on the etching target film, wherein the photoresist pattern includes a first exposure pattern on the etching target film and a second exposure pattern on the first exposure pattern, wherein forming the photoresist pattern comprises: forming a first photoresist film on the etching target film; forming the first exposure pattern by removing at least a portion of the first photoresist film through a first exposure process; forming a second photoresist film on the first exposure pattern; and forming the second exposure pattern by removing at least a portion of the second photoresist film through a second exposure process, wherein the photoresist pattern has a thickness that decreases from a central portion to an edge portion thereof.

According to an aspect of the inventive concept, there is provided a method of forming patterns for a semiconductor device, the method including forming an etching target film on a substrate; forming a photoresist film on the etching target film; and converting the photoresist film to an exposure pattern through an exposure process using a photomask, wherein a central portion of the photomask is more light transmittable than an edge portion of the photomask.

According to an aspect of the inventive concept, there is provided a method of forming patterns for a semiconductor device, the method including forming a photomask assembly by arranging a plurality of photomasks, wherein at least one of the photomasks overlaps another of the photomasks; forming an etching target film on a substrate; forming a photoresist film on the etching target film; and converting the photoresist film to an exposure pattern through an exposure process using the photomask assembly, wherein, in the photomask assembly, a number of the photomasks that overlap each other increases from an edge portion of the photomask assembly to a central portion of the photomask assembly.

### BRIEF DESCRIPTION OF THE DRAWINGS

Embodiments will be more clearly understood from the following detailed description taken in conjunction with the accompanying drawings in which:

FIG. 1 is a diagram illustrating stepped patterns of a semiconductor device, according to some embodiments;

FIGS. 2A, 2B, 2C, 2D, 2E, 2F, and 2G are diagrams illustrating a method of forming patterns for a semiconductor device, according to some embodiments;

FIGS. 3A and 3B are diagrams illustrating a method of forming patterns for a semiconductor device, according to some embodiments; and

FIGS. 4A and 4B are diagrams illustrating a method of forming patterns for a semiconductor device, according to some embodiments.

### DETAILED DESCRIPTION OF THE INVENTION

Hereinafter, the embodiments are described in detail with reference to the attached drawings. The same reference numerals may be used for the same components in the drawings unless clearly stated otherwise and duplicate descriptions thereof may be omitted.

Since these embodiments can be modified in various ways and have various embodiments, specific embodiments may be illustrated in the drawings and described in detail in the detailed description. However, this is not intended to limit the scope to specific embodiments and shall be understood to include all transformations, equivalents, and substitutes included in the disclosed technical scope. In describing embodiments, when it is determined that the detailed description of related known technologies can obscure the point, the detailed description may be omitted.

Embodiments herein may be described with reference to cross-sectional views and/or plan views, which are ideal illustrations. In the drawings, the thicknesses of films and regions may be exaggerated for effective explanation of technical content. Accordingly, the form of the illustrations may be modified depending on manufacturing technology and/or tolerance. Accordingly, embodiments are not limited to the specific form shown but also include changes in form produced according to the manufacturing process. For example, an etched region shown at a right angle may be rounded or have a shape with a certain curvature. Accordingly, the regions illustrated in the drawings have schematic properties and the shapes of the regions illustrated in the drawings are intended to illustrate a specific shape of the region of the device and are not intended to limit the scope of the inventive concept.

Hereinafter, embodiments are described in detail with reference to the drawings.

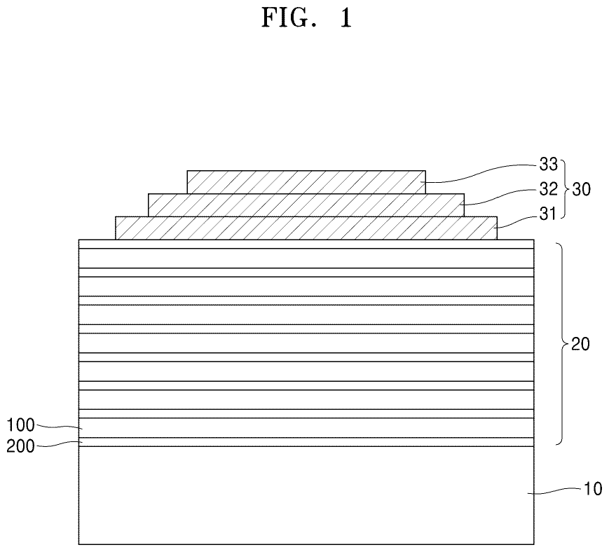

FIG. 1 is a diagram briefly illustrating stepped patterns of a semiconductor device, according to some embodiments. According to FIG. 1 an etching target film 20 that includes horizontal films 100 and interlayer insulating films 200 may be on a substrate 10. A stepped photoresist pattern 30 that includes a first exposure pattern 31, a second exposure pattern 32, and a third exposure pattern 33 may be on the etching target film 20.

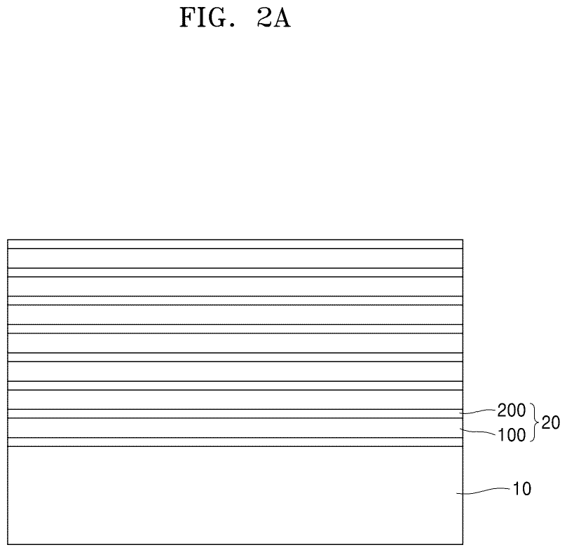

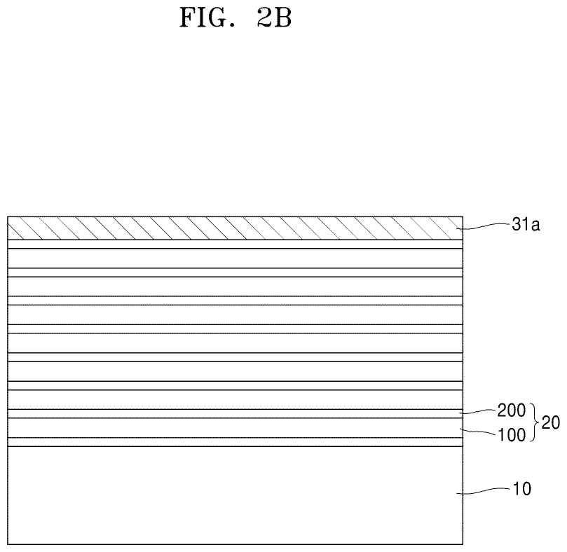

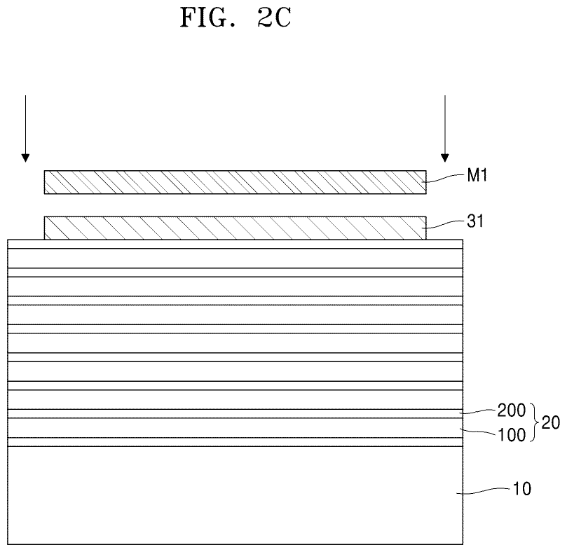

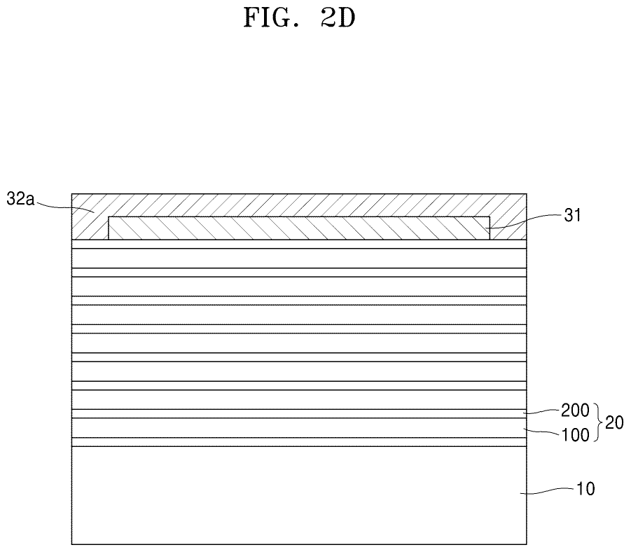

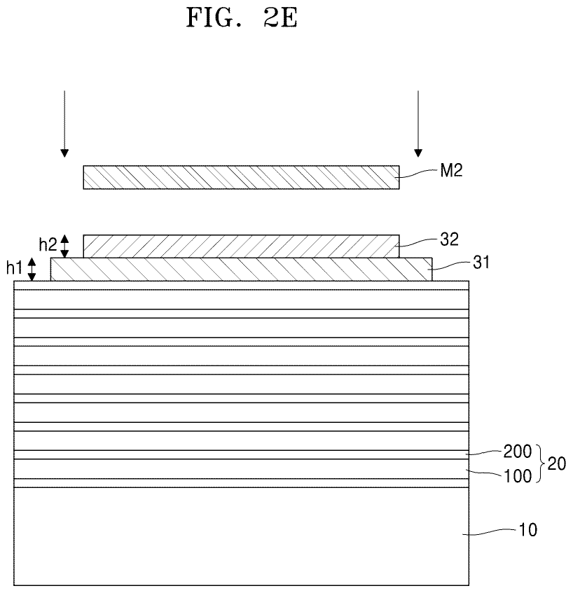

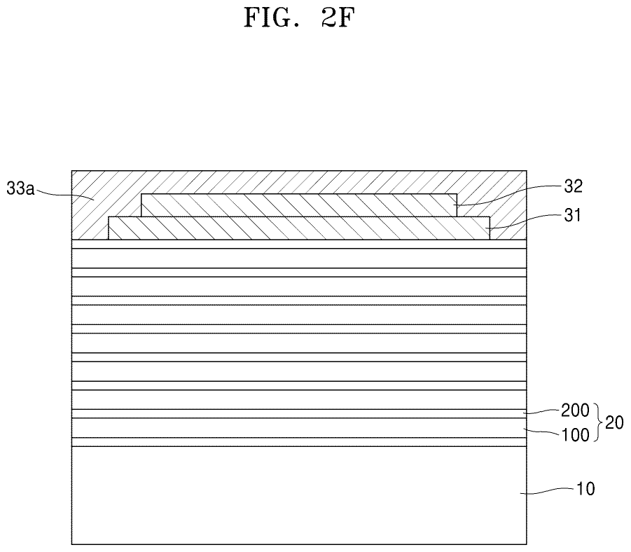

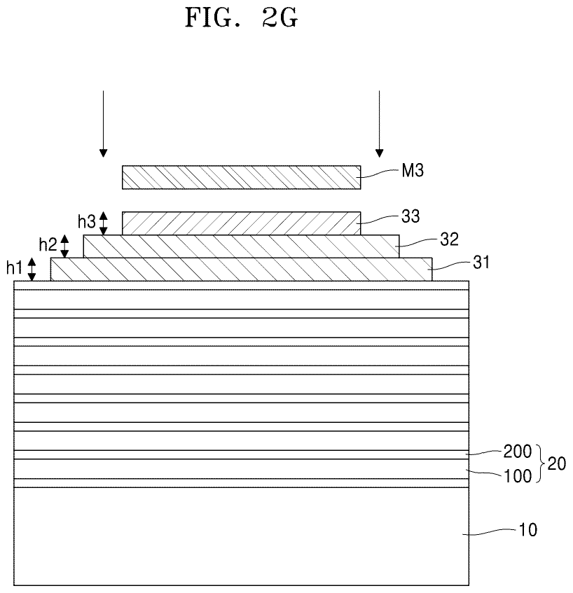

FIGS. 2A, 2B, 2C, 2D, 2E, 2F, and 2G are diagrams illustrating a method of forming patterns for a semiconductor device, according to some embodiments.

Referring to FIG. 2A, an etching target film 20 may be formed on a substrate 10. The substrate 10 may include a material with semiconductor properties (e.g., silicon), an insulating material (e.g., glass), and/or a semiconductor or a conductor covered or overlapped by the insulating material. As used herein, the term “and/or” includes any and all combinations of one or more of the associated listed items. The etching target film 20 may include a plurality of vertically stacked films. According to some embodiments, the etching target film 20 may be formed by alternately and repeatedly stacking two materials having etch selectivity to each other. For example, the etching target film 20 may include horizontal films 100 and interlayer insulating films 200, which are alternately stacked on the substrate 10. The horizontal films 100 may include a material that has etch selectivity to the interlayer insulating films 200. For example, the interlayer insulating films 200 may include a silicon oxide film, and the horizontal films 100 may include a silicon nitride film, a silicon oxynitride film, a polycrystalline silicon film, and/or a metal film. In some embodiments, (some of or each of) the horizontal films 100 may include the same material.

According to some embodiments, the etching target film 20 may be formed as a single layer or may be formed by stacking a plurality of layers. For example, the etching target film 20 may include a plurality of stacked insulating films and may include conductive patterns or semiconductor patterns between the stacked insulating films.

Referring to FIG. 2B, a first photoresist film 31a may be formed on (applied onto) the etching target film 20. The first photoresist film 31a may be formed using, for example, a spin-on-coating method. In some embodiments, the first photoresist film 31a may be thicker than the etching target film 20. In some embodiments, the first photoresist film 31a may include a positive photoresist of which portions that receive light (i.e., exposure patterns) are removed by a developer and may include a photo-acid generator (PAG). The positive photoresist may include a resist (a photoresist) for KrF excimer laser (e.g., 248 nm wavelength), a resist (a photoresist) for ArF excimer laser (e.g., 193 nm wavelength), a resist (a photoresist) for F2 excimer laser (157 nm wavelength), and/or a resist (a photoresist) for extreme ultraviolet (EUV) light (e.g., 13.5 nm wavelength). The PAG may include, for example, a chromophore group and may generate acid when exposed to light, for example, the KrF excimer laser, the ArF excimer laser, the F2 excimer laser, and/or the EUV light.

After forming the first photoresist film 31a on the etching target film 20, a soft bake process may be performed. For example, the soft bake process may be performed at a temperature of (about) 110° C. to (about) 120° C. for (about) 1 minute to (about) 5 minutes. This soft bake process may improve the curing and adhesion properties of the first photoresist film 31a.

Referring to FIG. 2C, a first exposure pattern 31 may be formed by performing a first exposure process using a first photomask M1.

The first exposure pattern 31 may correspond to a portion of the first photoresist film 31a that is not converted (by the first exposure process) into a material which can be removed by a developer. For example, the first exposure pattern 31 may be formed by removing at least a portion of the first photoresist film 31a through the first exposure process.

In some embodiments, the first photomask M1 may include quartz or silica-based glass but the inventive concept is not limited thereto.

The first photomask M1 may have a smaller area (a size less) than the etching target film 20 in a plan view. The first photomask M1 may be included in (within) the horizontal cross-section of the etching target film 20 in a plan view. The horizontal cross-sectional area (size) of the first exposure pattern 31 may be smaller (less) than the horizontal cross-sectional area (size) of an upper surface of the etching target film 20.

Referring to FIG. 2D, a second photoresist film 32a may be formed on (to cover or overlap) the first exposure pattern 31. The second photoresist film 32a may include (may be made of) (substantially) the same material as the first photoresist film 31a (see FIG. 2B).

In some embodiments, the second photoresist film 32a may be on (e.g., may cover or overlap) an upper surface and side surfaces of the first exposure pattern 31 and have a conformal upper surface but the inventive concept is not limited thereto.

Referring to FIG. 2E, a second exposure pattern 32 may be formed on the first exposure pattern 31 by performing a second exposure process using a second photomask M2.

The second exposure pattern 32 may have (substantially) the same material as the first exposure pattern 31. The second exposure pattern 32 may correspond to a portion of the second photoresist film 32a that is not converted (by the second exposure process) into a material which can be removed by a developer. For example, the second exposure pattern 32 may be formed by removing at least a portion of the second photoresist film 32a through the second exposure process.

In some embodiments, the second photomask M2 may be the same mask as the first photomask M1 (see FIG. 2C) but the inventive concept is not limited thereto.

The area (size) of the second photomask M2 may be smaller (less) than that of the first exposure pattern 31 in a plan view. The second photomask M2 may be included in (within) the horizontal cross-section of the first exposure pattern 31 in a plan view. The horizontal cross-sectional area (size) of the second exposure pattern 32 may be smaller (less) than the horizontal cross-sectional area (size) of the first exposure pattern 31.

The height (thickness) h2 of the second exposure pattern 32 (in a vertical direction that is perpendicular to the upper surface of the etching target film 20) may be the same as (equal to) the height (thickness) h1 of the first exposure pattern 31 (in the vertical direction). In some embodiments, the height h1 of the first exposure pattern 31 may be different from the height h2 of the second exposure pattern 32.

Referring to FIG. 2F, a third photoresist film 33a may be formed on (e.g., to cover or overlap) the first exposure pattern 31 and the second exposure pattern 32. The third photoresist film 33a may include (substantially) the same material as the second photoresist film 32a (see FIG. 2D).

In some embodiments, the third photoresist film 33a may cover (or overlap) an upper surface and side surfaces of each of the first and second exposure patterns 31 and 32 and have a conformal upper surface but the inventive concept is not limited thereto.

Referring to FIG. 2G, a third exposure pattern 33 may be formed on the second exposure pattern 32 by performing a third exposure process using a third photomask M3.

The third exposure pattern 33 may include (substantially) the same material as the second exposure pattern 32. The third exposure pattern 33 may correspond to a portion of the third photoresist film 33a that is not converted into a material which can be removed by a developer. For example, the third exposure pattern 33 may be formed by removing at least a portion of the third photoresist film 33a through the third exposure process.

In some embodiments, the third photomask M3 may be the same mask as the second photomask M2 (see FIG. 2E) but the inventive concept is not limited thereto.

The area (size) of the third photomask M3 may be smaller (less) than that of the second exposure pattern 32 in a plan view. The third photomask M3 may be included in (within) the horizontal cross-section of the second exposure pattern 32 in a plan view. As a result, the horizontal cross-sectional area (size) of the third exposure pattern 33 may be smaller (less) than the horizontal cross-sectional area (size) of the second exposure pattern 32.

The height (thickness) h3 of the third exposure pattern 33 (in the vertical direction) may be the same as (equal to) the height (thickness) h2 of the second exposure pattern 32. The heights (thicknesses) h1, h2, and h3 of the first, second, and third exposure patterns 31, 32, and 33 may be the same (equal). However, in some embodiments, the height h2 of the second exposure pattern 32 may be different from the height h3 of the third exposure pattern 33.

Through the processes of FIGS. 2A, 2B, 2C, 2D, 2E, 2F, and 2G, a stepped photoresist pattern 30 of FIG. 1 may be formed. The stepped photoresist pattern 30 may include the first, second, and third exposure patterns 31, 32, and 33.

The method of forming patterns for a semiconductor device described with reference to FIGS. 2A, 2B, 2C, 2D, 2E, 2F, and 2G may include a method of gradually forming the photoresists of different thicknesses for each region by repeatedly performing photoresist coating and exposure processes.

When using a photolithography process to form fine patterns, the probability of a loading effect at an edge portion is relatively higher than at a central portion with respect to one unit block. The loading effect occurs due to differences in etch rate due to differences in pattern density and pattern critical dimension (CD). According to some embodiments, to improve the not-open defects that may occur at the edge portion, the photoresist pattern at the edge portion may be made thinner than the photoresist pattern at the central portion. Herein, a central portion of an element may include the center of the element (in a plan view). An edge portion of the element may refer to a non-central portion of the element. A central portion of an element may be closer to the center of the element than an edge portion of the element.

Although the stepped photoresist pattern 30 is shown as having a total of three layers in the vertical direction in FIG. 1, this is only an example. A stepped photoresist pattern having two or more than three layers may be formed by repeatedly applying the processes described with reference to FIGS. 2A, 2B, 2C, 2D, 2E, 2F, and 2G.

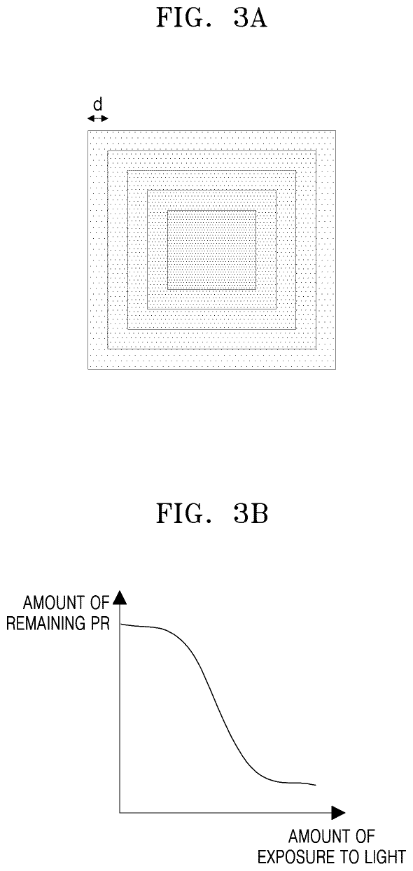

FIGS. 3A and 3B are diagrams illustrating a method of forming patterns for a semiconductor device, according to some embodiments.

More specifically, FIG. 3A is a plan view illustrating the distribution density of fine particles (or fine polygons) included in the photomask (e.g. the first photomask M1, the second photomask M2, or the third photomask M3) and FIG. 3B is a cross-sectional view schematically illustrating the correlation between the amount of light reaching the photoresist film and the amount of the remaining photoresists (PR).

Referring to FIG. 3A, in one photomask, each unit area may have a different layout. Specifically, the density of fine particles may decrease toward the edge portion of the cell and may increase toward the central portion of the cell.

In some embodiments, polygons (fine polygons) with a pitch not greater than 50 nanometers may be inserted into the photomask for each region. In FIG. 3A, the photomask is shown in a rectangular shape, but this is only an example. Other types of layouts are also possible when the density of fine particles in the central portion is greater than in the edge portion.

Referring again to FIG. 3A, the width of dimension d of the region having the same density (of fine particles or fine polygons) in the layout may range from about several micrometers to about tens of micrometers. For example, in the layout, the width of dimension d of the region having the same density (of fine particles or fine polygons) may be from about 1 micrometer to about 50 micrometers. However, the inventive concept is not limited to the above example range.

As shown in FIG. 3A, when the density of the polygons (fine polygons) inserted into the photomask is set to increase from the edge portion to the central portion thereof, the greater the amount of light that passes through the mask and reaches the photoresist film, i.e., the amount of light exposed to the photoresist film, the smaller the amount of the remaining photoresists during the exposure process using a photoresist with a low contrast ratio (i.e., low contrast PR) as shown in the graph of FIG. 3B. Thus, like the stepped photoresist pattern 30 shown in FIG. 1, a stepped pattern in which the edge portion is thinner than the central portion may be obtained. The central portion of the photomask may have a greater light transmittal feature (may be more light transmittable) than the edge portion of the photomask. For example, the density of one or more polygons in the central portion of the photomask may be greater than the density of one or more polygons in the edge portion of the photomask.

In some embodiments, the low contrast PR may include a material having a deep ultraviolet (DUV)-based contrast ratio that is not greater than 10 candela (cd). For example, the low contrast PR may include a material with a DUV-based contrast ratio that is not greater than 5 cd.

The method of forming patterns for a semiconductor device described with reference to FIGS. 3A and 3B may include a method of forming a stepped photoresist pattern (e.g., the stepped photoresist pattern 30) by inserting fine polygons included in the photomask at different densities for each area, i.e., inserting fine polygons of which the density increases from the edge portion to the central portion, to design the layout of the photomask, and using the low contrast PR for the photomask.

As stated above, to improve the not-open defects, the photoresist pattern formed at the edge portion may be made thinner than the photoresist pattern formed at the central portion because the reliability of the device may decrease due to the loading effect that occurs at the edge portion.

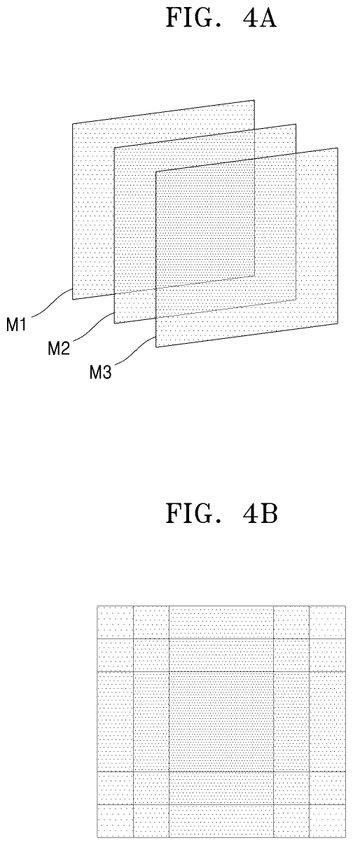

FIGS. 4A and 4B are diagrams illustrating a method of forming patterns for a semiconductor device, according to some embodiments.

More specifically, FIG. 4A is a schematic projection view of a plurality of photomasks which are stacked to gradually overlap and FIG. 4B is a diagram illustrating the relative intensity of each region when an exposure process is performed by adding a plurality of photomasks as shown in FIG. 4A.

Referring to FIG. 4A, a plurality of (identical) photomasks may be prepared. In FIG. 4A, a total of three photomasks M1, M2, and M3 are shown but this is only an example. The number of photomasks is not limited thereto.

In some embodiments, the plurality of (identical) photomasks may be shifted and arranged so that some portions thereof overlap (overlap more) with each other and the other portions thereof do not overlap (or overlap less). As a result, a region where two or more photomasks overlap may have lower relative light transmittance than a region where two or more photomasks do not overlap. Among regions where photomasks overlap, regions where a greater number of photomasks overlap may have lower relative light transmittance than regions where the photomasks do not overlap (or regions where a smaller number of photomasks overlap).

When an exposure process is performed with multiple photomasks overlapped by arranging the angles and positions of the photomasks differently so that more photomasks overlap from the edge portion to the central portion, an intensity distribution (e.g., the distribution of the (fine) polygons or the distribution of the (fine) particles) similar to the layout of FIG. 4B may be obtained.

When the exposure process is performed using the low contrast PR after placing the plurality of photomasks as above, the greater the amount of light that passes through the mask and reaches the photoresist film, that is, the greater the amount of light exposed to the photoresist film, the smaller the amount of the remaining photoresists may be (see FIG. 3B). Thus, the stepped photoresist pattern 30 (see FIG. 1) in which the edge portion has high transmittance due to less overlap of photomasks has a less photoresist thickness than the central portion which has low transmittance due to more overlap of photomasks may be obtained.

The method of forming patterns for a semiconductor device described with reference to FIGS. 4A and 4B may include a method of forming a stepped photoresist pattern (e.g., the stepped photoresist pattern 30) in which the photoresist pattern is less polished from the edge portion to the central portion by arranging multiple identical photomasks so that some thereof overlap, and performing an exposure process using the photomask arranged as above and the low contrast PR.

As stated above, to improve the not-open defects, the photoresist pattern formed at the edge portion may be made thinner than the photoresist pattern formed at the central portion because the reliability of the device may decrease due to the loading effect that occurs at the edge portion.

While the inventive concept has been particularly shown and described with reference to embodiments thereof, it will be understood that various changes in form and details may be made therein without departing from the scope of the following claims.

What is claimed is:

1. A method of forming patterns for a semiconductor device, the method comprising:
forming an etching target film on a substrate; and
forming a photoresist pattern on the etching target film, wherein the photoresist pattern includes a first exposure pattern on the etching target film and a second exposure pattern on the first exposure pattern,
wherein forming the photoresist pattern comprises:
forming a first photoresist film on the etching target film;
forming the first exposure pattern by removing at least a portion of the first photoresist film through a first exposure process;
forming a second photoresist film on the first exposure pattern; and
forming the second exposure pattern by removing at least a portion of the second photoresist film through a second exposure process,
wherein the photoresist pattern has a thickness that decreases from a central portion to an edge portion thereof.

2. The method of claim 1, wherein the second exposure pattern is within the first exposure pattern in a plan view.

3. The method of claim 1, wherein forming the second photoresist film on the first exposure pattern comprises forming the second photoresist film on side surfaces and an upper surface of the first exposure pattern.

4. The method of claim 1, wherein an area of an upper surface of the first exposure pattern is less than an area of an upper surface of the etching target film.

5. The method of claim 1, wherein the photoresist pattern has a stepped shape in a cross-sectional view, and
wherein a first thickness of a central portion of the photoresist pattern is greater than a second thickness of an edge portion of the photoresist pattern.

6. The method of claim 1, wherein the etching target film comprises horizontal films and interlayer insulating films that are alternately stacked on the substrate.

7. The method of claim 1, the first photoresist film and the second photoresist film include a same material.

8. The method of claim 1, wherein the first exposure pattern and the second exposure pattern have an equal thickness.

9. A method of forming patterns for a semiconductor device, the method comprising:
forming an etching target film on a substrate;
forming a photoresist film on the etching target film; and
converting the photoresist film to an exposure pattern through an exposure process using a photomask,
wherein a central portion of the photomask is more light transmittable than an edge portion of the photomask.

10. The method of claim 9, wherein the exposure pattern has a stepped shape in a cross-sectional view, and
wherein a thickness of a central portion of the exposure pattern is greater than a thickness of an edge portion of the exposure pattern.

11. The method of claim 9, wherein the photomask comprises polygons that have a pitch less than 50 nanometers, and
wherein respective ones of the polygons have different densities from one another.

12. The method of claim 11, wherein a first density of one or more the polygons in the central portion of the photomask is greater than a second density of one or more the polygons in the edge portion of the photomask.

13. The method of claim 9, wherein the exposure process is a single process.

14. The method of claim 9, wherein the etching target film comprises horizontal films and interlayer insulating films that are alternately stacked on the substrate.

15. The method of claim 9, wherein the photoresist film includes a positive photoresist.

16. A method of forming patterns for a semiconductor device, the method comprising:
forming a photomask assembly by arranging a plurality of photomasks, wherein at least one of the photomasks overlaps another of the photomasks;
forming an etching target film on a substrate;
forming a photoresist film on the etching target film; and
converting the photoresist film to an exposure pattern through an exposure process using the photomask assembly,
wherein, in the photomask assembly, a number of the photomasks that overlap each other increases from an edge portion of the photomask assembly to a central portion of the photomask assembly.

17. The method of claim 16, wherein the exposure pattern has a stepped shape in a cross-sectional view, and
wherein a thickness of a central portion of the exposure pattern is greater than a thickness of an edge portion of the exposure pattern.

18. The method of claim 16, wherein the exposure process is a single process.

19. The method of claim 16, wherein the etching target film comprises horizontal films and interlayer insulating films which are alternately stacked on the substrate.

20. The method of claim 16, wherein the photomasks are identical.
